(19) United States
(12) Patent Application Publication
(10) Pub. No.: US 2026/0152844 A1
(43) Pub. Date: Jun. 4, 2026

(54) ALUMINUM-SCANDIUM ALLOY SPUTTERING TARGET AND PREPARATION METHOD THEREOF

(71) Applicant: INDUSTRIAL TECHNOLOGY RESEARCH INSTITUTE, Hsinchu (TW)

(72) Inventors: Yu-Chen KAO, Zhudong Township (TW); Yu-Ming CHEN, Taipei City (TW); Yu-Han WU, Zhunan Township (TW)

(73) Assignee: INDUSTRIAL TECHNOLOGY RESEARCH INSTITUTE, Hsinchu (TW)

(21) Appl. No.: 19/193,540

(22) Filed: Apr. 29, 2025

(30) Foreign Application Priority Data
Dec. 2, 2024 (TW) 113146567

(51) Int. Cl. C23C 14/34

(52) U.S. Cl. CPC C23C 14/3414

(57) ABSTRACT

An aluminum-scandium alloy sputtering target composes essentially of 10 at % to 50 at % of scandium and 90 at % to 50 at % of aluminum. The aluminum-scandium alloy sputtering target has microstructure that includes a metallic aluminum matrix and an aluminum-scandium intermetallic phase in the metallic aluminum matrix. The aluminum-scandium intermetallic phase includes Al₃Sc, Al₂Sc, or AlSc. At any two different positions on the aluminum-scandium alloy sputtering target, the difference in scandium content is 1 at % or less, and at any two different positions on the surface of the aluminum-scandium alloy sputtering target, the difference in the aluminum-scandium grain sizes is 13 μm or less.

### CROSS REFERENCE TO RELATED APPLICATIONS

This application claims priority of Taiwan Patent Application No. 113146567, filed on Dec. 2, 2024, the entirety of which is incorporated by reference herein.

### TECHNICAL FIELD

The present disclosure relates to an alloy sputtering target and a preparation method thereof, and, in particular, it relates to an aluminum-scandium alloy sputtering target and a preparation method thereof.

### BACKGROUND

As the frequency bands of next-generation communication filters such as global 5G/6G/WiFi 7 are gradually expanded from N41 to N77, the demand for aluminum-scandium alloy targets is increasing. Aluminum-scandium alloy targets with high scandium content can improve the piezoelectric coefficient and electromechanical coupling coefficient and reduce the loss of signal transmission. Therefore, demand for aluminum-scandium alloy targets is increasing.

Since the large differences in melting point and density between aluminum and scandium, it is difficult to produce aluminum-scandium alloy targets and the composition is not uniform. Nowadays, aluminum-scandium alloy targets are usually produced by vacuum melting, casting, and hot rolling processes. The higher the content of scandium, which has a high melting point, the harder and more brittle aluminum-scandium intermetallic compounds are formed during the hot rolling process, making the aluminum-scandium alloy targets difficult to process and form. In addition, the surface of the aluminum-scandium alloy target tends to oxidize in a high-temperature environment, resulting in the oxygen content of the aluminum-scandium alloy target being too high, which affects the coating quality.

### SUMMARY

The present disclosure provides an aluminum-scandium alloy sputtering target capable of achieving small and uniform grain size, low oxygen content, and/or uniform composition without post heat treatment, and a preparation method thereof.

One embodiment of the present disclosure provides an aluminum-scandium (Al—Sc) alloy sputtering target consisting essentially of 10 at % to 50 at % scandium and 90 at % to 50 at % aluminum. The aluminum-scandium alloy sputtering target has a microstructure that includes a metallic aluminum matrix and an aluminum-scandium intermetallic phase in the metallic aluminum matrix. The aluminum-scandium intermetallic phase includes Al₃Sc, Al₂Sc, or AlSc. At any two different positions on the aluminum-scandium alloy sputtering target, the difference in scandium content is 1 at % or less, and at any two different positions on the surface of the aluminum-scandium alloy sputtering target, the difference in the aluminum-scandium grain sizes is 13 μm or less.

One embodiment of the present disclosure provides an aluminum-scandium alloy sputtering target which is prepared by a method that includes providing aluminum and scandium in an atomic ratio of 90:10 to 50:50 in a melting tank. The method includes performing a first vacuum arc melting process on the aluminum and the scandium in an inert gas environment to form a plurality of alloy ingots. The method includes arranging the alloy ingots in a melting tank, wherein the distance between adjacent alloy ingots is 5 mm or less. The method includes performing a second vacuum arc melting process in an inert gas environment to melt the alloy ingots to form an aluminum-scandium alloy target embryo. The method includes cooling the aluminum-scandium alloy target embryo to form an aluminum-scandium alloy sputtering target. The average cooling rate for the aluminum-scandium alloy target embryo is greater than or equal to 5° C./min and less than 24° C./min. The purity of the aluminum is 4N or higher, and the purity of the scandium is 4N or higher.

One embodiment of the present disclosure provides a preparation method of an aluminum-scandium alloy sputtering target. The method includes providing aluminum and scandium in an atomic ratio of 90:10 to 50:50 in a melting tank. The method includes performing a first vacuum arc melting process on the aluminum and the scandium in an inert gas environment to form a plurality of alloy ingots. The method includes arranging the alloy ingots in a melting tank, wherein the distance between adjacent alloy ingots is 5 mm or less. The method includes performing a second vacuum arc melting process in an inert gas environment to melt the alloy ingots to form an aluminum-scandium alloy target embryo. The method includes cooling the aluminum-scandium alloy target embryo to form an aluminum-scandium alloy sputtering target. The average cooling rate for the aluminum-scandium alloy target embryo is greater than or equal to 5° C./min and less than 24° C./min. The purity of the aluminum is 4N or higher, and the purity of the scandium is 4N or higher.

### BRIEF DESCRIPTION OF THE DRAWINGS

In order to make the purpose, features and advantages of the present disclosure clearer and easier to understand, the specific implementation methods of the present disclosure are described in detail below with reference to the accompanying drawings.

FIG. 1 is a flow chart of a preparation method of an aluminum-scandium alloy sputtering target according to an embodiment of the present disclosure.

FIG. 2A is a schematic top view of an aluminum-scandium alloy sputtering target according to an embodiment of the present disclosure.

FIG. 2B is a schematic side view of an aluminum-scandium alloy sputtering target according to an embodiment of the present disclosure.

FIG. 3 is an XRD diagram of an aluminum-scandium alloy sputtering target according to an embodiment of the present disclosure.

FIG. 4 is an XRD diagram of an aluminum-scandium alloy sputtering target according to another embodiment of the present disclosure.

### DETAILED DESCRIPTION

It will be further understood that the terms “includes” and/or “comprises” when used in this specification, specify the presence of the stated features, integers, steps, operations, elements, components, and/or groups thereof but do not preclude the presence or addition of one or more other features, integers, steps, operations, elements, components, and/or groups thereof. It will also be understood that the singular forms “a” and “an” when used in this specification, they are intended to include the plural forms as well, unless expressly stated otherwise.

It should be understood that, although the terms “first”, “second” etc. are used herein to describe various steps, elements, components, regions, layers and/or parts, these steps, elements, components, regions, layers and/or parts should not be limited by these terms. These terms are only used to distinguish one steps, elements, components, regions, layers, and/or parts from other steps, elements, components, regions, layers, and/or parts.

It should be understood that the methods described herein include steps, and additional steps may be provided before, during and/or after the steps described. Some of the steps described may be substituted or deleted in different embodiments. Although some embodiments have been discussed as performing the steps in a particular order, the steps may be performed in any other logical order.

The expression “a to b” or “a-b” used herein for a specific range of values is defined as “≤a and ≥b”. The term “at %” used herein is based on the assumption that the sum of all atoms is 100 at %. For example, the expression “10 at % to 50 at % scandium” used herein means that scandium is 10% to 50% of the sum of all atoms.

One embodiment of the present disclosure provides an aluminum-scandium (Al—Sc) alloy sputtering target consisting essentially of 10 at % to 50 at % of scandium and 90 at % to 50 at % of the aluminum. The aluminum-scandium alloy sputtering target has microstructure that includes a metallic aluminum matrix and an aluminum-scandium intermetallic phase in the metallic aluminum matrix. The aluminum-scandium intermetallic phase includes Al₃Sc, Al₂Sc, or AlSc. At any two different positions on the aluminum-scandium alloy sputtering target, the difference in scandium content is 1 at % or less, and at any two different positions on the surface of the aluminum-scandium alloy sputtering target, the difference in the aluminum-scandium grain sizes is 13 μm or less. The oxygen content of the aluminum-scandium alloy sputtering target is 100 ppm or less.

The aluminum-scandium alloy sputtering target disclosed herein may include 10 at % to 50 at % of the scandium and 90 at % to 50 at % of the aluminum. In some embodiments, the aluminum-scandium alloy sputtering target may further include unavoidable impurities. In some embodiments, the aluminum-scandium alloy sputtering target may be formed from the aluminum and the scandium by a melting process, but the present disclosure is not limited thereto. In some embodiments, the aluminum-scandium alloy sputtering target may be formed using 10 at % to 45 at % of the scandium and 90 at % to 55 at % of the aluminum. In some embodiments, the aluminum-scandium alloy sputtering target may include 12 at % to 44 at %, 13 at % to 43 at %, 40 at %, or 30 at % of the scandium. In some embodiments, the aluminum-scandium alloy sputtering target may include of 56 at % to 88 at %, 57 at % to 87 at %, 70 at %, or 60 at % of the aluminum.

The aluminum-scandium alloy sputtering target disclosed herein may include an aluminum-scandium intermetallic phase. The properties (e.g., thermal expansion coefficient and mechanical properties) of the aluminum-scandium alloy sputtering target can be controlled by the aluminum-scandium intermetallic phase. In some embodiments, the microstructure of the aluminum-scandium alloy sputtering target includes one or more aluminum-scandium intermetallic phases, and each aluminum-scandium intermetallic phase may include Al₃Sc, Al₂Sc, or AlSc. In some embodiments, the aluminum-scandium intermetallic phase in the microstructure of the aluminum-scandium alloy sputtering target is uniformly distributed in the metallic aluminum matrix.

The scandium is evenly distributed throughout the aluminum-scandium alloy sputtering target. Specifically, the difference in the scandium content of the entire aluminum-scandium alloy sputtering target is 1 at % or less. That is, the difference in the scandium content measured at any two different positions in the entire aluminum-scandium alloy sputtering target will be less than or equal to 1 at % at most.

In some embodiments, the aluminum-scandium alloy sputtering target may include an average aluminum-scandium grain size of less than 60 μm. The smaller the aluminum-scandium grain size, the higher the sputtering uniformity, the lower the defect density, and the higher the density of the sputtered film formed by the aluminum-scandium alloy sputtering target. The term “average aluminum-scandium grain size” in the present disclosure refers to the average of the Al—Sc grain size measured from five sites including the center, top edge, bottom edge, left edge, and right edge of a single surface of the Al—Sc alloy sputtering target. In some embodiments, the average aluminum-scandium grain size of the aluminum-scandium alloy sputtering target may be less than or equal to 60 μm, less than or equal to 55 μm, or less than or equal to 50 μm. In some embodiments, the average aluminum-scandium grain size of the aluminum-scandium alloy sputtering target may be greater than or equal to 10 μm, greater than or equal to 15 μm, or greater than or equal to 17 μm. In some embodiments, the average aluminum scandium grain size of the aluminum scandium alloy sputtering target may be greater than or equal to 10 μm and less than 60 μm, such as 15 μm, 20 μm, 25 μm, 30 μm, 35 μm, 40 μm, 45 μm, 50 μm or 55 μm.

In some embodiments, the aluminum-scandium grains in the aluminum-scandium alloy sputtering target are uniform in size. For example, on the surface of the aluminum-scandium alloy sputtering target, the difference in the aluminum-scandium grain sizes of the aluminum-scandium alloy sputtering target is 13 μm or less. That is, the difference in the grain size of the aluminum-scandium alloy sputtering target measured at two different positions on the surface of the aluminum scandium alloy sputtering target will not exceed 13 μm. In some embodiments, the difference in the aluminum-scandium grain sizes of the aluminum-scandium alloy sputtering target is 10 μm or less.

In some embodiments, the oxygen content of the aluminum-scandium alloy sputtering target may be 100 ppm or less. The lower the oxygen content of the aluminum-scandium alloy sputtering target, the better the quality of the sputtered film. In some embodiments, the oxygen content of the aluminum-scandium alloy sputtering target may be less than or equal to 90 ppm, 80 ppm, 70 ppm, or 60 ppm.

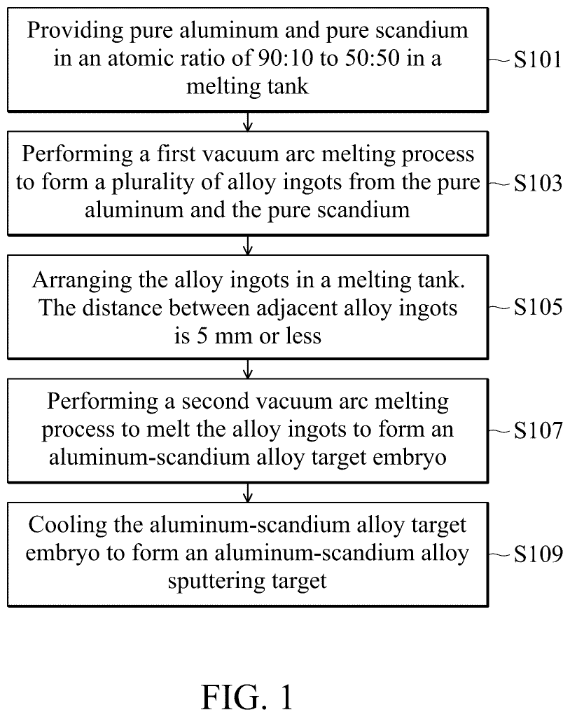

Another embodiment of the present disclosure provides a preparation method of an aluminum-scandium alloy sputtering target and an aluminum-scandium alloy sputtering target prepared by the method. FIG. 1 is a flow chart of a preparation method of an aluminum-scandium alloy sputtering target according to an embodiment of the present disclosure. As shown in FIG. 1, the preparation method of the aluminum-scandium alloy sputtering target of the present disclosure includes the following steps. Step S101 involves providing pure aluminum and pure scandium in an atomic ratio of 90:10 to 50:50 in a melting tank. Step S103 involves performing a first vacuum arc melting process to form a plurality of alloy ingots from the pure aluminum and the pure scandium. Step S105 involves arranging the alloy ingots in a melting tank. The distance between adjacent alloy ingots is 5 mm or less. Step S107 involves performing a second vacuum arc melting process to melt the alloy ingots to form an aluminum-scandium alloy target embryo. Step S109 involves cooling the aluminum-scandium alloy target embryo to form an aluminum-scandium alloy sputtering target. Furthermore, in step S107, the average cooling rate for the aluminum-scandium alloy target embryo is greater than or equal to 5° C./min and less than 24° C./min. The purity of the pure aluminum is 4N or higher, and the purity of the pure scandium is 4N or higher.

In step S101, the pure aluminum and the pure scandium are provided in an atomic ratio of 90:10 to 50:50 in a melting tank. By providing the aluminum and scandium in the above atomic ratio, the subsequently formed aluminum-scandium alloy sputtering target can have a smaller aluminum-scandium grain size. In some embodiments, the atomic ratio of aluminum to scandium may be from 88:12 to 56:44, from 87:13 to 57:43, from 60:40 to 70:30. In some embodiments, the melting tank may include a vacuum arc melting furnace, but the disclosure is not limited thereto.

The first vacuum arc melting process in step S103 can be performed in an inert gas environment after step S101 to form a plurality of alloy ingots. In some embodiments, the first vacuum arc melting process in step S103 may include generating a first arc in the melting tank (such as a vacuum arc melting furnace) at a first voltage of 10 to 30 V and a first current of 200 to 600 A in an argon environment of 100 to 250 Torr. In some embodiments, the first vacuum arc melting process is performed in an argon environment at 150 to 220 Torr, such as 160 Torr, 180 Torr, or 200 Torr, but the disclosure is not limited thereto. In some embodiments, the first arc in the first vacuum arc melting process is generated at a first voltage of 15 to 25V or 18 to 20V and a first current of 250 to 600 A, but the disclosure is not limited thereto.

In some embodiments, the method may further include performing a purification process before the first vacuum arc melting process in step S103. Specifically, the purification process may include, after placing the aluminum and the scandium in the vacuum arc melting furnace and closing a door of the vacuum arc melting furnace, evacuating a chamber of the vacuum arc melting furnace to 3×10⁻² Torr, and then introducing argon gas to about 50 to 60 Torr. The purification process may be performed one or more times as needed. For example, in some embodiments, the purification process may be repeated 3 to 4 times. After the purification process, the chamber of the vacuum arc melting furnace may be evacuated to 2×10⁻² Torr, and then filled with an argon gas at 100 to 250 Torr to perform the first vacuum arc melting process in step S103.

The alloy ingots are formed in the first vacuum arc melting process in step S103. The alloy ingot formed in step S103 may be taken out after cooling. In some embodiments, the alloy ingots formed in step S103 can be taken out after cooling by injecting 500 Torr of argon gas into the chamber of the vacuum arc melting furnace, but the present disclosure is not limited thereto.

The alloy ingot formed in step S103 may include 10 at % to 50 at % of the scandium and 50 at % to 90 at % of the aluminum. In some embodiments, the alloy ingot may include 10 at % to 45 at %, 13 at % to 40 at %, 10 at % to 30 at %, or 15 at % to 30 at % of the scandium. In some embodiments, the alloy ingot may include 55 at % to 90 at %, 60 at % to 90 at %, 70 at % to 90 at %, or 60 at % to 80 at % of the aluminum. In some embodiments, the alloy ingot may have a weight of 75 to 175 g, e.g., 80 g, 90 g, 100 g, 110 g, 130 g, or 150 g.

The alloy ingots formed in step S103 are placed in a melting tank in step S105. The number of the alloy ingots placed in the melting tank depends on the size of the melting tank. In some embodiments, the melting tank may include a vacuum arc melting furnace. Specifically, in some embodiments, 3 to 4 alloy ingots formed in step S103 may be evenly arranged in the melting tank to perform the second vacuum arc melting process in step S107, wherein the distance between adjacent alloy ingots may be less than or equal to 5 mm.

The second vacuum arc melting process in step S107 is performed after step S105. In some embodiments, the second vacuum arc melting process in step S107 may be performed in an inert gas environment to melt the alloy ingots to form an aluminum-scandium alloy target embryo. In some embodiments, the second vacuum arc melting process in step S107 includes generating a second arc at a second voltage of 10 to 30 V and a second current of 200 to 600 A in the melting tank (such as a vacuum arc melting furnace) in an argon environment of 100 to 250 Torr. In some embodiments, the second vacuum arc melting process is performed in an argon environment of 150 to 220 Torr, such as 160 Torr, 180 Torr or 200 Torr, but the present disclosure is not limited thereto. In some embodiments, the second arc in the second vacuum arc melting process is generated at a second voltage of 15 to 25V or 18 to 20V and a second current of 250 to 600 A, but the present disclosure is not limited thereto. The second vacuum arc melting process in step S107 can melt edges of the alloy ingots formed in step S103 into a molten metal. Thus, adjacent alloy ingots can be joined to form an aluminum-scandium alloy target embryo.

In some embodiments, the method may further include performing a purification process between step S105 and step S107. Specifically, the purification process may include closing a door of the vacuum arc melting furnace, evacuating a chamber of the vacuum arc melting furnace to 3×10⁻² Torr, and then introducing argon gas to about 50 to 60 Torr after step S105. The purification process may be performed one or more times as needed. For example, in some embodiments, the purification process may be repeated 3 to 4 times. After the purification process, the chamber of the vacuum arc melting furnace may be evacuated to 2×10⁻² Torr, and then filled with argon gas at 100 to 250 Torr to perform the second vacuum arc melting process in step S107.

After the aluminum-scandium alloy target embryo formed in step S107 is cooled in step S109 at an average cooling rate greater than or equal to 5° C./min and less than 24° C./min, it may be taken out from the vacuum arc melting furnace to obtain the aluminum-scandium alloy sputtering target disclosed herein. Cooling the aluminum-scandium alloy target embryo formed in step S107 at an average cooling rate within the above range in step S109 can prevent cracks from forming in the resulting aluminum-scandium alloy sputtering target. Accordingly, the aluminum-scandium alloy sputtering target prepared from the preparation method of the aluminum-scandium alloy sputtering target disclosed herein may not have cracks visible to the naked eye. In some embodiments, the average cooling rate in step S109 may be greater than or equal to 6° C./min and less than or equal to 20° C./min or greater than or equal to 6° C./min and less than or equal to 15° C./min.

In some embodiments, the aluminum-scandium alloy sputtering target prepared from the preparation method of the aluminum-scandium alloy sputtering target disclosed herein may include a microstructure. The microstructure includes a metallic aluminum matrix and an aluminum-scandium intermetallic phase in the metallic aluminum matrix. The aluminum-scandium intermetallic phase includes Al₃Sc, Al₂Sc, or AlSc. The microstructure may include one or more aluminum-scandium intermetallic phase, and each aluminum-scandium intermetallic phase may include Al₃Sc, Al₂Sc, or AlSc. In some embodiments, the aluminum-scandium intermetallic phase in the microstructure of the aluminum-scandium alloy sputtering target is uniformly distributed in the metallic aluminum matrix. Scandium is evenly distributed throughout the aluminum-scandium alloy sputtering target. For example, in some embodiments, at any two different positions on the aluminum-scandium alloy sputtering target, the difference in scandium content is 1 at % or less, and at any two different positions on the surface of the aluminum-scandium alloy sputtering target, the difference in the aluminum-scandium grain sizes is 13 μm or less.

In some embodiments, the aluminum-scandium alloy sputtering target prepared from the preparation method of the aluminum-scandium alloy sputtering target disclosed herein may include an average aluminum-scandium grain size of less than 60 km. In some embodiments, the average aluminum-scandium grain size may be less than or equal to 58 m, less than or equal to 55 μm, or less than or equal to 50 μm. In some embodiments, the average aluminum-scandium grain size may be greater than or equal to 10 μm, greater than or equal to 15 μm, or greater than or equal to 17 μm. In some embodiments, the average aluminum-scandium grain size may be greater than or equal to 10 μm and less than 60 μm, greater than or equal to 15 μm and less than or equal to 55 μm, or greater than or equal to m and less than or equal to 50 μm.

In some embodiments, the oxygen content of the aluminum-scandium alloy sputtering target prepared from the preparation method of an aluminum-scandium alloy sputtering target disclosed herein may be 100 ppm or less. The lower the oxygen content of the aluminum-scandium alloy sputtering target, the better the quality of the sputtered film. In some embodiments, the oxygen content of the aluminum-scandium alloy sputtering target prepared from the preparation method of an aluminum-scandium alloy sputtering target disclosed herein may be less than or equal to 90 ppm, 80 ppm, 70 ppm, or 60 ppm.

In summary, in some embodiments, the aluminum-scandium alloy sputtering target prepared from the preparation method of the aluminum-scandium alloy sputtering target disclosed herein not only has no cracks visible to the naked eye, but also has the advantages of small and uniform grain size, low oxygen content, and/or uniform composition without the need for post-heat treatment.

Specific embodiments are provided below to further illustrate the features and advantages of the present disclosure. However, those skilled in the art should understand that the present disclosure is not limited to the specific embodiments disclosed below.

### Example 1

Mount a copper mold on a water cooling tank so that the heat from the copper mold is dissipated by flowing water throughout the process. Close a door of a vacuum arc melting furnace after placing an aluminum ingot having a purity of 4N or more and scandium powder having a purity of 4N or more in the copper mold in the vacuum arc melting furnace at an atomic ratio of 86.4:13.6. A chamber of the vacuum arc melting furnace was evacuated to 3×10⁻² Torr, argon gas was introduced into the chamber of the vacuum arc melting furnace to about 50 to 60 Torr, and then evacuated. After repeating the above steps 3 to 4 times, the chamber pressure of the chamber of the vacuum arc melting furnace was evacuated to 2×10⁻² Torr and argon gas was introduced to about 180 Torr. A pure titanium ingot was melted to check for residual oxygen inside (yellow surface means the titanium ingot was oxidized). After confirming that the titanium ingot is normal, the first vacuum arc melting process was used to melt the above aluminum ingot and the scandium powder. The first vacuum arc melting process includes generating an arc at a voltage of 20V and a current of 400 A in an argon environment in the chamber pressure of 180 Torr to melt the aluminum ingot and the scandium powder to form three alloy ingots, wherein each alloy ingot weighs approximately 125 g. The alloy ingots were taken out after cooling by water under the copper mold until the original metallic color of the alloy ingots was restored and the temperature in the chamber of the vacuum arc melting furnace was lowered.

The above alloy ingots were placed in a copper mold in a vacuum arc melting furnace with a spacing of less than or equal to 5 mm. A door of the vacuum arc melting furnace was closed and a chamber of the vacuum arc melting furnace was evacuated to vacuum. The chamber of the vacuum arc melting furnace was evacuated to 3×10⁻² Torr, argon gas was introduced into the chamber of the vacuum arc melting furnace to about 50 to 60 Torr, and then evacuated. After repeating the above steps 3 to 4 times, the chamber pressure of the chamber of the vacuum arc melting furnace was evacuated to 2×10⁻² Torr and argon gas was introduced to about 180 Torr. The pure titanium ingots were melted to check whether there is residual oxygen inside (yellow surface means that the titanium ingot is oxidized). After confirming that the titanium ingot is normal, the second vacuum arc melting process was used to melt the above alloy ingots. The second vacuum arc melting process includes generating an arc at a voltage of 20V and a current of 400 A in an argon environment in the chamber pressure of 180 Torr to melt the above alloy ingots. Edges of the alloy ingots were melted into a molten metal in the second vacuum arc melting process, and adjacent alloy ingots can be joined to form an aluminum-scandium alloy target embryo.

The formed aluminum-scandium alloy target embryo was cooled at an average cooling rate of about 12° C./min and then taken out from the vacuum arc melting furnace to obtain an aluminum-scandium alloy sputtering target of Example 1.

### Example 2

The aluminum-scandium alloy sputtering target of Example 2 was prepared in the same manner as the aluminum-scandium alloy sputtering target of Example 1, except that the aluminum ingot and the scandium powder at an atomic ratio of 70:30 were used to form an aluminum-scandium alloy ingot containing 30 at % of the scandium and 70 at % of the aluminum, and the aluminum-scandium alloy target embryo was cooled at an average cooling rate of about 10° C./min.

### Example 3

The aluminum-scandium alloy sputtering target of Example 3 was prepared in the same manner as the aluminum-scandium alloy sputtering target of Example 1, except that the aluminum ingot and the scandium powder at an atomic ratio of 60:40 were used to form an aluminum-scandium alloy ingot containing 40 at % of the scandium and 60 at % of the aluminum, and the aluminum-scandium alloy target embryo was cooled at an average cooling rate of about 8° C./min.

### Comparative Example 1

The aluminum-scandium alloy sputtering target of Comparative Example 1 was prepared in the same manner as the aluminum-scandium alloy sputtering target of Example 1, except that the aluminum-scandium alloy target embryo was cooled at an average cooling rate of about 24° C./min.

### Comparative Example 2

The aluminum-scandium alloy sputtering target of Comparative Example 2 was prepared in the same manner as the aluminum-scandium alloy sputtering target of Example 2, except that the aluminum-scandium alloy target embryo was cooled at an average cooling rate of about 24° C./min.

### Comparative Example 3

Mount a copper mold on a water cooling tank so that the heat from the copper mold is dissipated by flowing water throughout the process. Close a door of a vacuum arc melting furnace and evacuate a chamber of the vacuum arc melting furnace to vacuum after placing an aluminum ingot having a purity of 4N or more and scandium powder having a purity of 4N or more in the copper mold in the vacuum arc melting furnace at an atomic ratio of 70:30. The chamber of the vacuum arc melting furnace was evacuated to 3×10⁻² Torr, argon gas was introduced into the chamber of the vacuum arc melting furnace to about 50 to 60 Torr, and then evacuated. After repeating the above steps 3 to 4 times, the chamber pressure of the chamber of the vacuum arc melting furnace was evacuated to 2×10⁻² Torr and argon gas was introduced to about 180 Torr. A pure titanium ingot was melted to check for residual oxygen inside (yellow surface means the titanium ingot was oxidized). After confirming that the titanium ingot is normal, a vacuum arc melting process was used to melt the above aluminum ingot and the scandium powder. The vacuum arc melting process includes generating an arc at a voltage of 20V and a current of 400 A in an argon environment in the chamber pressure of 180 Torr to melt the aluminum ingot and the scandium powder to form an aluminum-scandium alloy target embryo. The aluminum-scandium alloy target embryo was cooled at an average cooling rate of about 24° C./min to obtain an aluminum-scandium alloy sputtering target of Comparative Example 3 (that is, in Comparative Example 3, the alloy ingot forming process was omitted, and the aluminum-scandium alloy sputtering target was made directly from the aluminum ingot and the scandium powder).

The process conditions of Examples 1 to 3 are listed in Table 1 below, and the process conditions of Comparative Examples 1 to 3 are listed in Table 2 below.

TABLE 1

| | Example 1 | Example 2 | Example 3 |
|---|---|---|---|
| Aluminum (Al) at % | 86.4 | 70 | 60 |
| Scandium (Sc) at % | 13.6 | 30 | 40 |
| First vacuum arc melting process | ◯ | ◯ | ◯ |
| First voltage (V) | 20 | 20 | 20 |
| First current (A) | 400 | 400 | 400 |
| Chamber pressure (Pa) | 180 | 180 | 180 |
| Second vacuum arc melting process | ◯ | ◯ | ◯ |
| Second voltage (V) | 20 | 20 | 20 |
| Second current (A) | 400 | 400 | 400 |
| Chamber pressure (Pa) | 180 | 180 | 180 |
| Average cooling rate (° C./min) | 12 | 10 | 8 |

TABLE 2

| | Comparative | Comparative | Comparative |
|---|---|---|---|
| | Example 1 | Example 2 | Example 3 |
| Aluminum (Al) at % | 86.4 | 70 | 70 |
| Scandium (Sc) at % | 13.6 | 30 | 30 |
| First vacuum arc melting | ◯ | ◯ | X |
| process | | | |
| First voltage (V) | 20 | 20 | — |
| First current (A) | 400 | 400 | — |
| Chamber pressure (Pa) | 180 | 180 | — |
| Second vacuum arc melting | ◯ | ◯ | ◯ |
| process | | | |
| Second voltage (V) | 20 | 20 | 20 |
| Second current (A) | 400 | 400 | 400 |
| Chamber pressure (Pa) | 180 | 180 | 180 |
| Average cooling rate | 24 | 24 | 24 |
| (° C./min) | | | |

### Evaluating the Properties of the Aluminum-Scandium Alloy Sputtering Targets

### Appearance Inspection

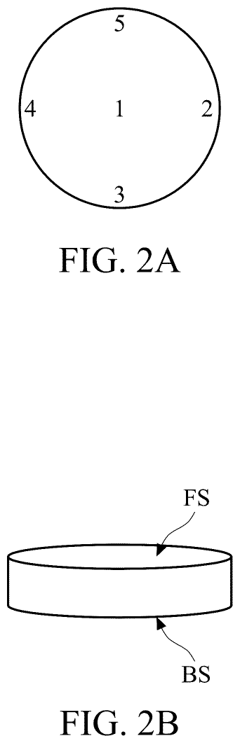

FIG. 2A is a schematic top view of an aluminum-scandium alloy sputtering target according to an embodiment of the present disclosure. FIG. 2B is a schematic side view of an aluminum-scandium alloy sputtering target according to an embodiment of the present disclosure. The appearance of the aluminum-scandium alloy sputtering targets of Examples 1 to 3 and Comparative Examples 1 to 3 were observed with the naked eye to check for cracks. The inspection results are shown in Table 3 below, where “X” indicates that no cracks are observed with the naked eye, “Δ” indicates that cracks are observed with the naked eye, and “O” indicates that the aluminum-scandium alloy sputtering target is observed to be cracked into several pieces with the naked eye.

### Aluminum-Scandium Grain Size Measurement

As shown in FIG. 2B, the aluminum-scandium alloy sputtering target according to the embodiment of the present disclosure includes a front side FS and a back side BS opposite to the front side FS. Aluminum-scandium grains at sites 1 to 5 (corresponding to the center, upper edge, lower edge, left edge, and right edge, respectively) marked in FIG. 2A were observed using a field emission electron microscope in a backscatter mode. Using built-in measurement software, select one grain from the aluminum-scandium grains at each site 1 to 5, measure the length or width of the grain and define it as the aluminum-scandium grain size at sites 1 to 5. The aluminum-scandium grain sizes at sites 1 to 5 in the front side FS of the aluminum-scandium alloy sputtering targets of Examples 1 to 3 and Comparative Examples 1 to 3 were measured. The aluminum-scandium grain sizes measured at sites 1 to 5 were averaged to obtain the average aluminum-scandium grain size of the aluminum-scandium alloy sputtering targets of Examples 1 to 3 and Comparative Examples 1 to 3. By comparing the aluminum-scandium grain sizes measured at sites 1 to 5, the difference in aluminum-scandium grain sizes (grain uniformity) of the aluminum-scandium alloy sputtering targets of Examples 1 to 3 and Comparative Examples 1 to 3 can be obtained. The obtained average aluminum scandium grain size and grain uniformity results are shown in Table 3 below.

### Scandium Content Measurement

According to the marked sites 1 to 5 in FIG. 2A, the aluminum-scandium grains at sites 1 to 5 were observed using a field emission electron microscope in a backscatter mode. Five 40*20 um areas were randomly selected under the field emission electron microscope at 500× magnification. The five 40*20 um areas were analyzed using an energy dispersive spectrometer to determine the scandium contents at sites 1 to 5 on the front side FS and the back side BS of the aluminum-scandium alloy sputtering targets of Examples 1 to 3 and Comparative Examples 1 to 3. By comparing the scandium contents measured at sites 1 to 5, the difference in scandium contents (composition uniformity) of the aluminum-scandium alloy sputtering targets of Examples 1 to 3 and Comparative Examples 1 to 3 can be obtained. The obtained composition uniformity results are shown in Table 3 below.

### Oxygen Content Measurement

The oxygen content of the aluminum-scandium alloy sputtering targets of Examples 1 to 3 and Comparative Examples 1 to 3 were measured using an oxygen, nitrogen and hydrogen analyzer. The resulting oxygen content measurement results are shown in

TABLE 3

| | | average | | | |
|---|---|---|---|---|---|
| | | aluminum- | | | |
| | | scandium | Oxygen | composition | grain |
| | | grain size | content | uniformity | uniformity |
| | crack | (μm) | (ppm) | (±at %) | (±μm) |
| Example 1 | X | 30 | 45 | 0.6 | 6 |
| Example 2 | X | 48 | 55 | 1 | 10 |
| Example 3 | X | 45 | 60 | 1 | 13 |
| Comparative | Δ | 90 | 43 | 2 | 15 |
| Example 1 | | | | | |
| Comparative | ◯ | 80 | 52 | 3 | 22 |
| Example 2 | | | | | |
| Comparative | ◯ | 60 | 40 | 5 | 32 |
| Example 3 | | | | | |

It can be seen from Tables 1 to 3 that the aluminum-scandium alloy sputtering target prepared at an average cooling rate equal to 24° C./min has cracks visible to the naked eye, and the aluminum-scandium alloy sputtering target prepared at an average cooling rate less than 24° C./min has no cracks visible to the naked eye. That is, the preparation method of the aluminum-scandium alloy sputtering target of the present disclosure can prepare a crack-free aluminum-scandium alloy sputtering target. It can be further seen from Tables 1 to 3 that the aluminum-scandium alloy sputtering target prepared according to the preparation method of the aluminum-scandium alloy sputtering target disclosed in the present disclosure has a smaller average aluminum-scandium grain size, better grain uniformity, and better composition uniformity, and the oxygen content of the aluminum-scandium alloy sputtering target can be less than 100 ppm.

### Example A

The aluminum-scandium alloy sputtering target of Example A was prepared in the same manner as the aluminum-scandium alloy sputtering target of Example 2, except that the aluminum-scandium alloy target embryo was cooled at an average cooling rate of 15° C./min.

### Example B

The aluminum-scandium alloy sputtering target of Example B was prepared in the same manner as the aluminum-scandium alloy sputtering target of Example 2, except that the aluminum-scandium alloy target embryo was cooled at an average cooling rate of 6° C./min.

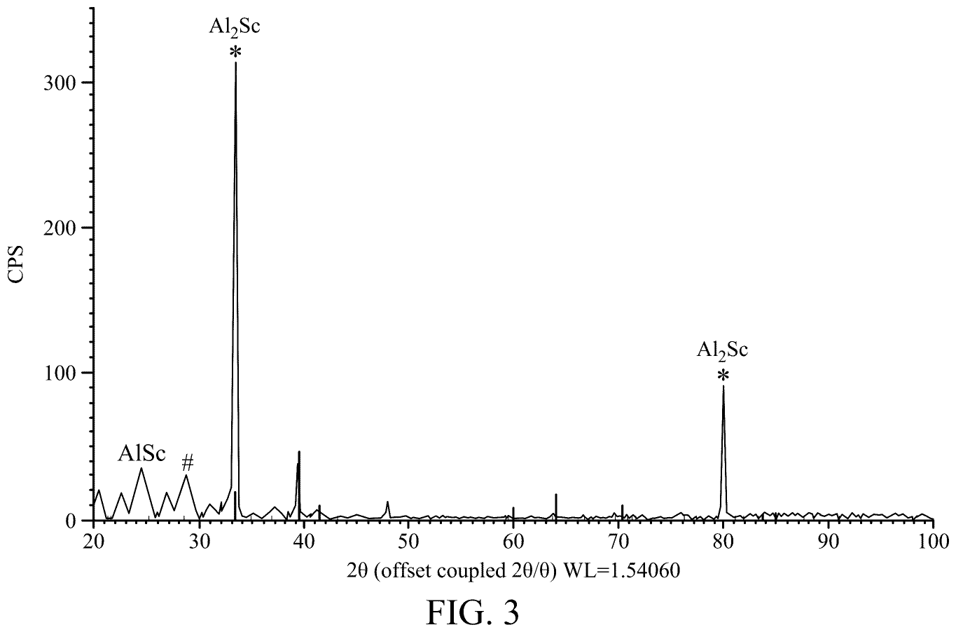

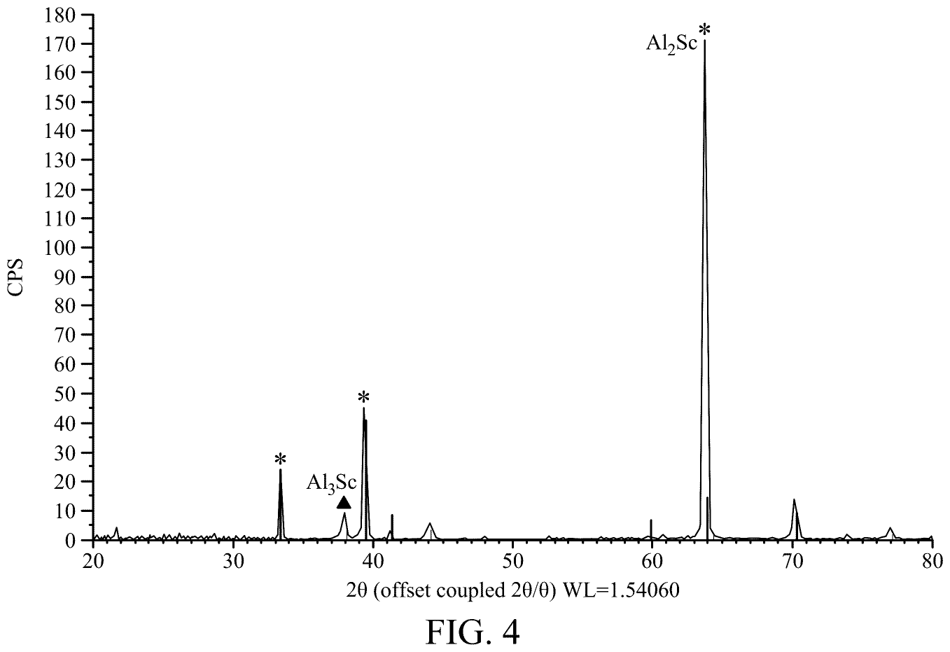

The aluminum-scandium intermetallic phases of the aluminum-scandium alloy sputtering targets of Example A and Example B were analyzed by a X-ray diffractometer and compared with a spectrum of a standard card. The results are shown in FIGS. 3 and 4. FIG. 3 is an XRD diagram of the aluminum-scandium alloy sputtering target of Example A. FIG. 4 is the XRD diagram of the aluminum-scandium alloy sputtering target of Example B.

As can be seen from FIG. 3 and FIG. 4, the aluminum-scandium alloy sputtering targets prepared from the preparation method of the aluminum-scandium alloy sputtering target according to the disclosed embodiment have one or more intermetallic aluminum-scandium phases including Al₃Sc, Al₂Sc, or AlSc. Specifically, as shown in FIG. 3, the aluminum-scandium alloy sputtering target prepared at an average cooling rate of 15° C./min has intermetallic aluminum-scandium phases including Al₂Sc and AlSc. As shown in FIG. 4, the aluminum-scandium alloy sputtering target prepared at an average cooling rate of 6° C./min has intermetallic aluminum-scandium phases including Al₂Sc and Al₃Sc. Therefore, it can be further seen from FIG. 3 and FIG. 4 that the aluminum-scandium alloy sputtering target prepared at different average cooling rates may have different intermetallic aluminum-scandium phases.

In summary, the preparation method of the aluminum-scandium alloy sputtering target disclosed herein can prepare a crack-free aluminum-scandium alloy sputtering target by performing two vacuum arc melting processes and adjusting the average cooling rate of cooling the aluminum-scandium alloy target embryo. The aluminum-scandium alloy sputtering target can have a smaller average aluminum-scandium grain size, better grain uniformity, and better composition uniformity.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An aluminum-scandium alloy sputtering target consists essentially of 10 at % to 50 at % of scandium and 90 at % to 50 at % of aluminum, comprising:
a microstructure comprising a metallic aluminum matrix and an aluminum-scandium intermetallic phase in the metallic aluminum matrix,
wherein the aluminum-scandium intermetallic phase comprises Al₃Sc, Al₂Sc, or AlSc, at any two different positions on the aluminum-scandium alloy sputtering target, the difference in scandium content is 1 at % or less, and at any two different positions on a surface of the aluminum-scandium alloy sputtering target, the difference in the aluminum-scandium grain sizes is 13 μm or less.

2. The aluminum-scandium alloy sputtering target as claimed in claim 1, wherein the aluminum-scandium alloy sputtering target consists essentially of 10 at % to 45 at % of scandium and 90 at % to 55 at % of aluminum.

3. The aluminum-scandium alloy sputtering target as claimed in claim 1, wherein an average aluminum-scandium grain size of the aluminum-scandium alloy sputtering target is less than 60 km.

4. The aluminum-scandium alloy sputtering target as claimed in claim 1, wherein the average aluminum-scandium grain size of the aluminum-scandium alloy sputtering target is greater than or equal to 10 km.

5. The aluminum-scandium alloy sputtering target as claimed in claim 1, wherein the difference in the aluminum-scandium grain sizes is 10 μm or less.

6. The aluminum-scandium alloy sputtering target as claimed in claim 1, wherein an oxygen content of the aluminum-scandium alloy sputtering target is 100 ppm or less.

7. The aluminum-scandium alloy sputtering target as claimed in claim 6, wherein the oxygen content of the aluminum-scandium alloy sputtering target is 60 ppm or less.

8. An aluminum-scandium alloy sputtering target prepared by a method, the method comprising:
providing pure aluminum and pure scandium in an atomic ratio of 90:10 to 50:50 in a melting tank;
performing a first vacuum arc melting process on the aluminum and the scandium in an inert gas environment to form a plurality of alloy ingots;
arranging the plurality of alloy ingots in a melting tank, wherein a distance between adjacent alloy ingots is 5 mm or less;
performing a second vacuum arc melting process in an inert gas environment to melt the plurality of alloy ingots to form an aluminum-scandium alloy target embryo; and
cooling the aluminum-scandium alloy target embryo to form the aluminum-scandium alloy sputtering target, wherein an average cooling rate for the aluminum-scandium alloy target embryo is greater than or equal to 5° C./min and less than 24° C./min, and the purity of the aluminum is greater than or equal to 4N and the purity of the scandium is greater than or equal to 4N.

9. The aluminum-scandium alloy sputtering target as claimed in claim 8, wherein the first vacuum arc melting process comprises generating a first arc in the melting tank at a first voltage of 10 to 30 V and a first current of 200 to 600 A in an argon environment of 100 to 250 Torr.

10. The aluminum-scandium alloy sputtering target as claimed in claim 8, wherein the second vacuum arc melting process comprises generating a second arc in the melting tank at a second voltage of 10 to 30 V and a second current of 200 to 600 A in an argon environment of 100 to 250 Torr.

11. The aluminum-scandium alloy sputtering target as claimed in claim 8, wherein the average cooling rate for the aluminum-scandium alloy target embryo is greater than or equal to 6° C./min and less than 15° C./min.

12. The aluminum-scandium alloy sputtering target as claimed in claim 8, wherein the average aluminum-scandium grain size of the aluminum-scandium alloy sputtering target is less than 60 km.

13. The aluminum-scandium alloy sputtering target as claimed in claim 8, wherein the difference in the aluminum-scandium grain sizes is 10 μm or less.

14. The aluminum-scandium alloy sputtering target as claimed in claim 8, wherein the oxygen content of the aluminum-scandium alloy sputtering target is 100 ppm or less.

15. A preparation method of an aluminum-scandium alloy sputtering target, comprising:
providing pure aluminum and pure scandium in an atomic ratio of 90:10 to 50:50 in a melting tank;
performing a first vacuum arc melting process on the aluminum and the scandium in an inert gas environment to form a plurality of alloy ingots;
arranging the plurality of alloy ingots in a melting tank, wherein a distance between adjacent alloy ingots is 5 mm or less;
performing a second vacuum arc melting process in an inert gas environment to melt the plurality of alloy ingots to form an aluminum-scandium alloy target embryo; and
cooling the aluminum-scandium alloy target embryo to form the aluminum-scandium alloy sputtering target, wherein the average cooling rate for the aluminum-scandium alloy target embryo is greater than or equal to 5° C./min and less than 24° C./min, and the purity of the aluminum is greater than or equal to 4N and the purity of the scandium is greater than or equal to 4N.

16. The preparation method of an aluminum-scandium alloy sputtering target as claimed in claim 15, wherein the first vacuum arc melting process comprises generating a first arc in the melting tank at a first voltage of 10 to 30 V and a first current of 200 to 600 A in an argon environment of 100 to 250 Torr.

17. The preparation method of an aluminum-scandium alloy sputtering target as claimed in claim 15, wherein the second vacuum arc melting process comprises generating a second arc in the melting tank at a second voltage of 10 to 30 V and a second current of 200 to 600 A in an argon environment of 100 to 250 Torr.

18. The preparation method of an aluminum-scandium alloy sputtering target as claimed in claim 15, wherein the average cooling rate for the aluminum-scandium alloy target embryo is greater than or equal to 6° C./min and less than 15° C./min.

19. The preparation method of an aluminum-scandium alloy sputtering target as claimed in claim 15, further comprising performing a purification process before performing the first vacuum arc melting process or the second vacuum arc melting process.

20. The preparation method of an aluminum-scandium alloy sputtering target as claimed in claim 15, wherein the pure aluminum and the pure scandium are provided in an atomic ratio of 88:12 to 56:44.
